(19) United States
(12) Patent Application Publication
(10) Pub. No.: US 2025/0191887 A1
(43) Pub. Date: Jun. 12, 2025

(54) METHOD FOR MANUFACTURING COMPONMENT AND COMPONENT

(71) Applicant: Tokyo Electron Limited, Tokyo (JP)

(72) Inventors: Ryou SON, Miyagi (JP); Masaru SASAKI, Miyagi (JP); Yasumasa ISHIHARA, Yamanashi (JP); Hiroshi FUJII, Miyagi (JP); Takahiro MURAKAMI, Miyagi (JP); Hideaki YAKUSHIJI, Miyagi (JP)

(73) Assignee: Tokyo Electron Limited, Tokyo (JP)

(21) Appl. No.: 19/038,877

(22) Filed: Jan. 28, 2025

Related U.S. Application Data
(63) Continuation of application No. PCT/JP2023/027263, filed on Jul. 25, 2023.

(30) Foreign Application Priority Data
Jul. 28, 2022 (JP) 2022-120798

(51) Int. Cl. H01J 37/32; C23C 16/455

(52) U.S. Cl. CPC H01J 37/3244; C23C 16/45565

(57) ABSTRACT

Provided is a method for manufacturing a component for a plasma processing apparatus, the method comprising steps of: (A) preparing a core material having a shape similar to but smaller than a final shape of the component; (B) forming a SiC stacked portion on the core material by forming a SiC film; and (C) removing at least a portion of the SiC stacked portion to form a SiC layer and process it into the final shape.

### CROSS-REFERENCE TO RELATED APPLICATIONS

This application is a bypass continuation application of International Application No. PCT/JP2023/027263 having an international filing date of Jul. 25, 2023 and designating the United States, the International Application being based upon and claiming the benefit of priority from Japanese Patent Application No. 2022-120798 filed on Jul. 28, 2022, the entire contents of each are incorporated herein by reference.

### TECHNICAL FIELD

The present disclosure relates to a manufacturing method and a component.

### BACKGROUND

An electrode, which is a component for a plasma processing apparatus, is manufactured, for example, by taking silicon carbide (SiC) that forms a film on a predetermined member and then cutting the SiC into a desired shape (such as by drilling a plurality of through holes for ejecting processing gas). Although SiC has the advantages of excellent hardness, heat resistance, and chemical stability, it has disadvantages that it takes a long time to form a film and is difficult to process.

For example, U.S. Pat. No. 10,096,471 discloses a manufacturing method for forming a shroud that is exposed to a plasma processing space and is made of SiC. In manufacturing this shroud, a SiC portion is formed on a graphite member, and then the member is removed from the SiC portion to obtain a shroud of a desired shape.

### SUMMARY

The present disclosure provides a technology capable of manufacturing a SiC-containing component for a plasma processing apparatus with high accuracy.

In accordance with an aspect of the present disclosure, there is provided is a method for manufacturing a component for a plasma processing apparatus, the method comprising steps of: (A) preparing a core material having a shape similar to but smaller than a final shape of the component; (B) forming a SiC stacked portion on the core material by forming a SiC film; and (C) removing at least a portion of the SiC stacked portion to form a SiC layer and process it into the final shape.

### BRIEF DESCRIPTION OF THE DRAWINGS

FIG. 1 is a schematic view showing a plasma processing apparatus using an electrode according to an embodiment.

FIG. 2 is an enlarged longitudinal sectional view showing the structure of an electrode according to a first embodiment.

FIG. 3 is a flowchart showing a method for manufacturing an electrode.

FIG. 4A is a longitudinal sectional view showing a pre-processed member that has undergone a core material preparing step. FIG. 4B is a longitudinal sectional view showing a processed body that has undergone a core material processing step. FIG. 4C is a longitudinal sectional view showing a film formed product that has undergone a SiC forming step. FIG. 4D is a longitudinal sectional view showing an upper electrode that has undergone a final shape processing step.

FIG. 5A is a longitudinal sectional view showing a member that has undergone a member preparing step according to a reference example. FIG. 5B is a longitudinal sectional view showing a film formed product that has undergone a SiC forming step according to a reference example. FIG. 5C is a longitudinal sectional view showing an upper electrode that has undergone a final shape processing step according to a reference example.

FIG. 6A is an explanatory view illustrating a state of manufacturing an electrode having a hole without a tapered portion. FIG. 6B is an explanatory view illustrating a state of manufacturing an electrode having a hole with a tapered portion according to a modification.

FIG. 7 is a longitudinal sectional view showing the flow of a method for manufacturing an electrode according to a second embodiment.

FIG. 8 is a longitudinal sectional view showing the flow of a method for manufacturing an electrode according to a third embodiment.

FIG. 9 is a longitudinal sectional view showing the flow of a method for manufacturing an electrode according to a fourth embodiment.

FIG. 10 is a longitudinal sectional view showing the flow of a method for manufacturing an electrode according to a fifth embodiment.

### DETAILED DESCRIPTION

Hereinafter, the exemplary embodiments of the present disclosure will be described with reference to the accompanying drawings. The same reference numerals are used throughout the drawings to designate the same or similar components.

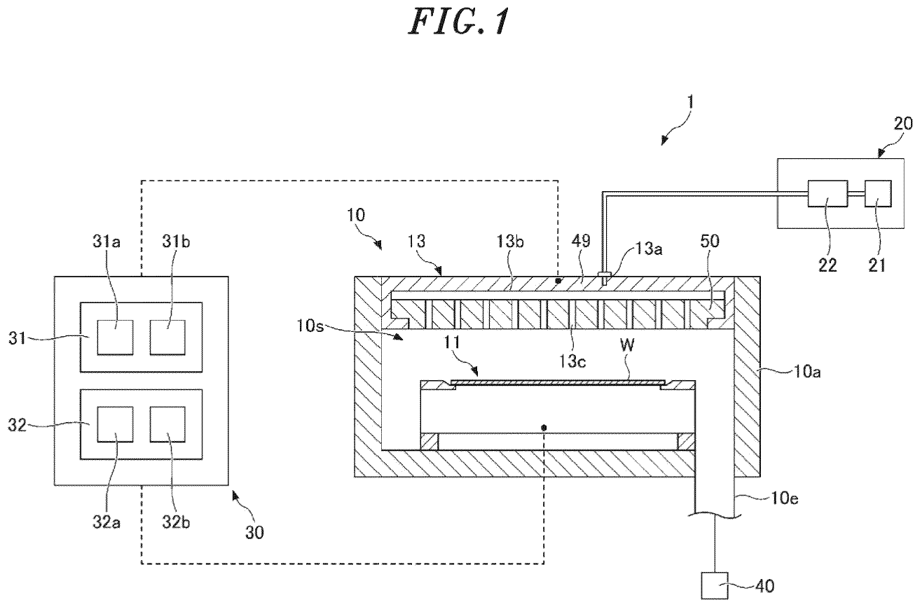

An electrode (upper electrode 50) manufactured by a manufacturing method according to an embodiment is one of components for a plasma processing apparatus 1, which is exposed to a plasma processing space 10s of the plasma processing apparatus 1, as shown in FIG. 1. For ease of understanding, a configuration example of a capacitively coupled plasma processing apparatus, which is an example of the plasma processing apparatus 1, will be described below with reference to FIG. 1.

The plasma processing apparatus 1 includes a plasma processing chamber 10, a gas supply 20, a power supply 30, and an exhaust system 40. The plasma processing apparatus 1 also includes a substrate support 11 and a gas introduction portion. The gas introduction portion is configured to introduce at least one processing gas into the plasma processing chamber 10. The gas introduction portion includes a showerhead 13. The substrate support 11 is disposed in the plasma processing chamber 10. The showerhead 13 is disposed above the substrate support 11 to face the substrate support 11. In one embodiment, the showerhead 13 forms at least a portion of a ceiling of the plasma processing chamber 10. The plasma processing chamber 10 has the plasma processing space 10s defined by the showerhead 13, a sidewall 10a of the plasma processing chamber 10, and the substrate support 11. The sidewall 10a is grounded. The showerhead 13 and the substrate support 11 are electrically isolated from a casing of the plasma processing chamber 10.

The showerhead 13 is configured to introduce at least one processing gas from the gas supply 20 into the plasma processing space 10s. The showerhead 13 has at least one gas supply port 13a, at least one gas diffusion chamber 13b, and a plurality of gas inlets 13c. The processing gas supplied to the gas supply port 13a passes through the gas diffusion chamber 13b and is introduced into the plasma processing space 10s from the plurality of gas inlets 13c. The showerhead 13 also includes a cooling plate 49 and an upper electrode 50 made of a conductive material. The upper electrode 50 has a plurality of through holes 52 which form the gas inlets 13c, and is exposed to the plasma processing space 10s. The cooling plate 49 supports the upper electrode 50.

The gas supply 20 may include at least one gas source 21 and at least one flow controller 22. In one embodiment, the gas supply 20 is configured to supply at least one processing gas from the corresponding gas source 21 through the corresponding flow controller 22 to the showerhead 13.

The power supply 30 includes an RF power supply 31 that is coupled to the plasma processing chamber 10 through at least one impedance matching circuit. The RF power supply 31 is configured to supply at least one RF signal (RF power), such as a source RF signal and a bias RF signal, to a lower electrode (not shown) of the substrate support 11 and/or the upper electrode 50 of the showerhead 13. Thus, plasma is formed from at least one processing gas supplied to the plasma processing space 10s. Therefore, the RF power supply 31 may function as at least a portion of a plasma generator configured to generate plasma from one or more processing gases in the plasma processing chamber 10. Furthermore, by supplying the bias RF signal to the lower electrode of the substrate support 11, a bias potential may be generated on a substrate W, and ion components in the formed plasma may be drawn into the substrate W.

In one embodiment, the RF power supply 31 includes a first RF generator 31a and a second RF generator 31b. The first RF generator 31a is coupled to the lower electrode of the substrate support 11 and/or the upper electrode 50 of the showerhead 13 via at least one impedance matching circuit, and is configured to generate the source RF signal (source RF power) for plasma generation. In one embodiment, the source RF signal has a frequency in the range of 13 MHz to 150 MHz. In one embodiment, the first RF generator 31a may be configured to generate multiple source RF signals having different frequencies. The generated source RF signal or signals are provided to the lower electrode of the substrate support 11 and/or the upper electrode 50 of the showerhead 13. The second RF generator 31b is coupled to the lower electrode of the substrate support 11 via at least one impedance matching circuit and is configured to generate the bias RF signal (bias RF power). In one embodiment, the bias RF signal has a lower frequency than the source RF signal. In one embodiment, the bias RF signal has a frequency in the range of 400 KHz to 13.56 MHZ. In one embodiment, the second RF generator 31b may be configured to generate multiple bias RF signals having different frequencies. The generated bias RF signal or signals are supplied to the lower electrode of the substrate support 11. In various embodiments, at least one of the source RF signal and the bias RF signal may be pulsed.

The power supply 30 may also include a DC power supply 32 coupled to the plasma processing chamber 10. The DC power supply 32 includes a first DC generator 32a and a second DC generator 32b. In one embodiment, the first DC generator 32a is configured to be connected to the lower electrode of the substrate support 11 and to generate a first DC signal. The generated first bias DC signal is applied to the lower electrode of the substrate support 11. In one embodiment, the first DC signal may be applied to other electrodes, such as an electrode in an electrostatic chuck. In one embodiment, the second DC generator 32b is configured to be connected to the upper electrode 50 of the showerhead 13 and to generate a second DC signal. The generated second DC signal is applied to the upper electrode 50 of the showerhead 13. In various embodiments, at least one of the first and second DC signals may be pulsed. The first and second DC generators 32a and 32b may be provided in addition to the RF power supply 31, or the first DC generator 32a may be provided in place of the second RF generator 31b.

The exhaust system 40 may be connected to a gas discharge port 10e provided on a bottom of the plasma processing chamber 10, for example.

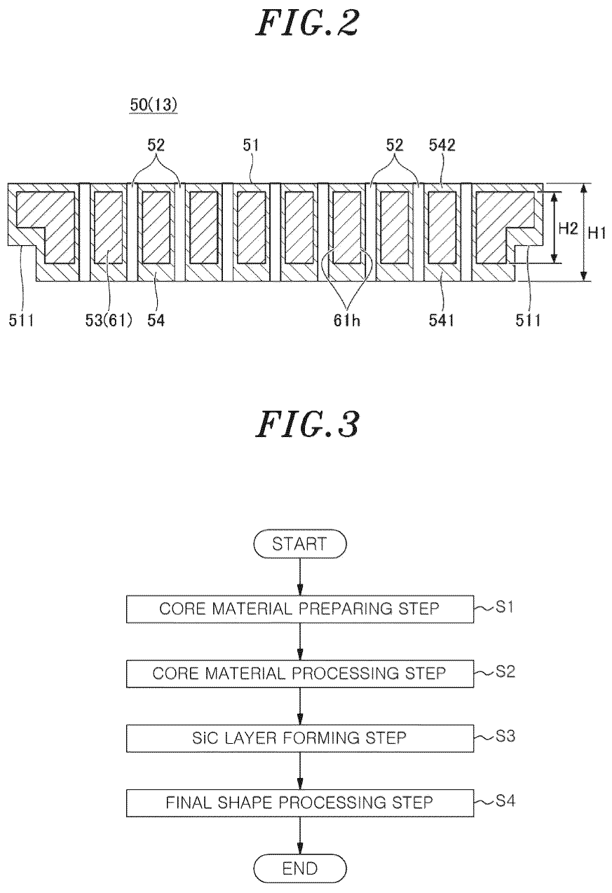

Next, the structure of the upper electrode 50 installed in the plasma processing apparatus 1 will be described with reference to FIG. 2.

As described above, the upper electrode 50 is disposed on the ceiling to generate plasma in the plasma processing space 10s by the RF power supplied from the power supply 30. Furthermore, the upper electrode 50 diffuses the processing gas supplied to the gas diffusion chamber 13b and introduces it into the plasma processing space 10s. Specifically, the upper electrode 50 has an electrode body 51 (component body) having a flat plate shape and a plurality of through holes 52 passing through both surfaces (upper and lower surfaces) of the electrode body 51.

The electrode body 51 may form substantially the entire ceiling of the plasma processing space 10s, and may expand the supplied RF power in a planar manner. The electrode body 51 is formed, for example, in a perfect circle shape in a plan view, and has a constant plate thickness from the center toward the outer periphery. The thickness of the electrode body 51 depends on the configuration of the plasma processing chamber 10, but is preferably set in the range of, for example, about 10 mm to 20 mm.

A stepped portion 511 is formed by cutting out the lower surface on the outer periphery of the electrode body 51. The showerhead 13 is fixed in place by a holding frame portion (cooling plate 49) protruding radially inward from the inner periphery of the plasma processing chamber 10 to hook onto the stepped portion 511 of the upper electrode 50 (see FIG. 1). Thus, the electrode body 51 is supported in a horizontal direction while facing (exposed to) the plasma processing space 10s.

The upper electrode 50 diffuses the processing gas by appropriately reducing the conductance of the processing gas supplied to the gas diffusion chamber 13b by the electrode body 51, while causing the processing gas to flow through the plurality of through holes 52 passing through the electrode body 51 into the plasma processing space 10s. For example, the through holes 52 are arranged at equal intervals from the center of the electrode body 51 toward the outside in the radial direction, and are also arranged at equal intervals along the circumferential direction on the same radius. However, the intervals between the through holes 52 are not limited to being equal.

Each through hole 52 has a perfect circle shape in a plan view, and is formed to have an inner diameter in the range of about 1 mm to 5 mm. The sizes of the through holes 52 may be set to be equal to or different from each other. For example, each through hole 52 near the center of the electrode body 51 may be formed with a small diameter, while each through hole 52 near the outer edge of the electrode body 51 may be formed with a large diameter. In addition, the number, arrangement, shape, etc. of the through holes 52 may be designed depending on the flow performance of the processing gas from the gas diffusion chamber 13b to the plasma processing space 10s.

The upper electrode 50 is formed using two types of materials when viewed in a cross section along the plate thickness direction. Specifically, the upper electrode 50 has a core material 53 located inside and a silicon carbide layer 54 (hereinafter referred to as a SiC layer 54) covering the core material 53. In particular, the upper electrode 50 according to this embodiment is configured by coating the entire surface of the core material 53 with the SiC layer 54.

The core material 53 is a member formed to be similar to, but smaller than, the final shape of the upper electrode 50. The core material 53 is preferably made of a material having high processability and heat resistance, such as graphite or a SiC sintered body. In this embodiment, the graphite is used as the core material 53. The graphite may withstand extremely low temperature to high temperature (e.g., 3000° C.) in a non-oxidizing atmosphere. The graphite is made of hexagonal plate-shaped crystals of carbon, and the faces of each layer are connected by strong covalent bonds, but the layers are connected by weak van der Waals forces, so it has excellent processability.

Therefore, the core material 53 formed of graphite may be easily processed into a target processing shape (hereinafter, referred to as a processed body 61) before the SiC layer 54 is stacked. The thickness H2 of the core material 53 (the thickness of the portion without the stepped portion 511) is preferably set to 0.5 to 0.9 times the thickness H1 of the plate of the electrode body 51 (the thickness of the portion without the stepped portion 511), which is the final shape. As an example, when the thickness H1 of the plate of the electrode body 51, which is the final shape, is 10 mm, the thickness H2 of the core material 53 may be set to 7 to 8 mm. By setting the thickness of the core material 53 to 50% or more of the plate thickness of the electrode body 51, the upper electrode 50 may be manufactured easily.

On the other hand, the SiC layer 54 is stacked on the surface of the core material 53 by performing a film forming process, for example, through a chemical vapor deposition (CVD) method on the processed body 61 of the core material 53. Thus, the upper electrode 50 has the SiC layer 54 with few impurities. Since the SiC layer 54 formed in this way has strong covalent bonds, it has high hardness and little loss of mechanical strength at high temperature. In addition, the SiC layer 54 may have excellent heat resistance to exhibit sufficient durability even in the high-temperature plasma processing space 10s. The SiC layer 54 applied to the upper electrode 50 is gradually volatilized by the plasma generated in the plasma processing space 10s, but this gas is exhausted from the plasma processing space 10s under the operation of the exhaust system 40. This prevents the SiC layer from becoming particles on the substrate W.

The SiC layer 54 is formed on both surfaces (upper and lower surfaces) and the peripheral surface of the core material 53, thereby covering the entire core material 53. However, it is preferable that a SiC layer 541 on the lower side of the core material 53 facing the plasma processing space 10s be formed thicker than a SiC layer 542 on the upper side opposite thereto. For example, the thickness of the lower SiC layer 541 is preferably set to be at least twice the thickness of the upper SiC layer 542. This enables the upper electrode 50 to promote a long life of the lower SiC layer 542 which is likely to contact plasma.

Moreover, the SiC layer 54 according to this embodiment is formed thinner than the core material 53. That is, the thickness of the SiC layer 54 (the sum of the thickness of the SiC layer 542 on the upper side and the SiC layer 541 on the lower side) is set to less than 50% of the plate thickness of the upper electrode 50. More preferably, the ratio of the thickness of the SiC layer 54 to the plate thickness of the upper electrode 50 is set in the range of 10% to 40%. If this thickness ratio is less than 10%, the amount of coverage of the SiC layer 54 as the electrode body 51 is reduced, so that there is a possibility that a lifespan for plasma becomes too short. Conversely, if the thickness ratio exceeds 40%, it takes a long time to form the SiC layer 54, which may reduce productivity.

For example, when the plate thickness of the upper electrode 50 is designed to be 10 mm, the thickness of the entire SiC layer 54 (the total thickness of the upper SiC layer 542 and the lower SiC layer 541) may be set to 2 to 3 mm. As an example, when the total thickness of the SiC layer 54 is 3 mm, the thickness of the lower SiC layer 541 may be set to 2 mm and the thickness of the upper SiC layer 542 may be set to 1 mm. In this way, by making the total thickness of the SiC layer 54, which is the sum of the upper SiC layer 542 and the lower SiC layer 541, thinner than the core material 53, the generation time of SiC layer 54 may be shortened.

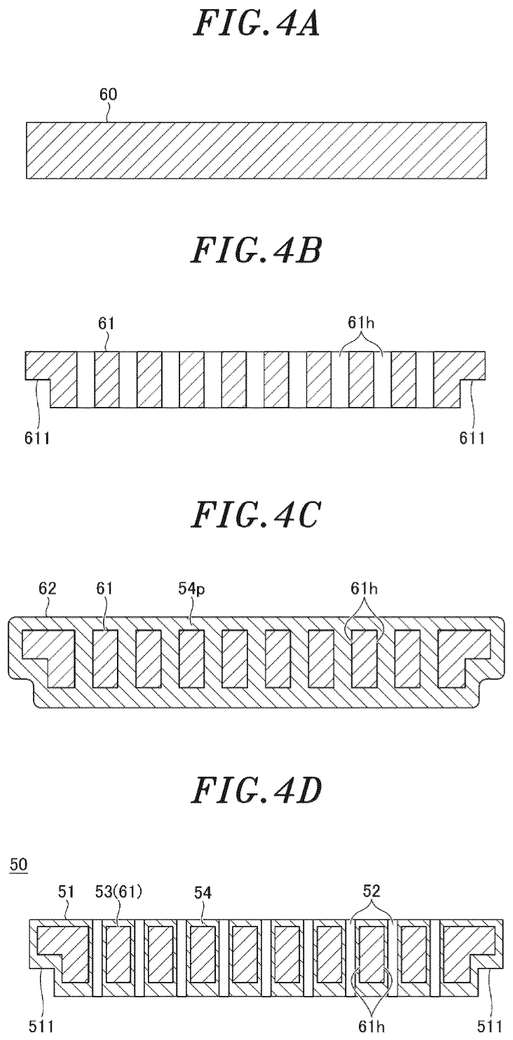

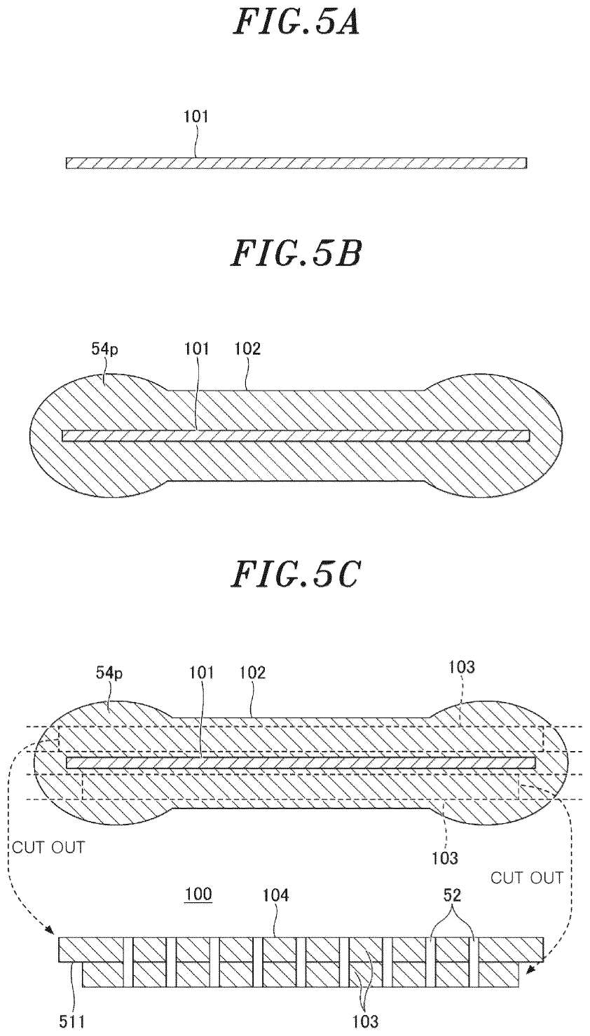

Next, a method for manufacturing the upper electrode 50 configured as above will be described in detail with reference to FIGS. 3 and 4. In the method for manufacturing the upper electrode 50, a core material preparing step S1, a core material processing step S2, a SiC layer forming step S3, and a final shape processing step S4 are performed in this order.

In the core material preparing step S1, a manufacturer prepares a pre-processed member 60 made of graphite and having a shape larger than the processed body 61, as shown in FIG. 4A. For example, in the core material preparing step, plate- or block-shaped graphite that has been acquired (purchased or manufactured) may be appropriately cut to form the pre-processed member 60. Of course, the acquired graphite itself may be used as the pre-processed member 60 as it is.

In the next core material processing step S2, the manufacturer processes the prepared pre-processed member 60 by cutting, polishing, or the like to form the processed body 61 to be used as the core material 53. For example, as shown in FIG. 4B, in the core material processing step, both the upper and lower surfaces of the pre-processed member 60 are cut so that the upper and lower surfaces are parallel to each other, and the outer periphery of the pre-processed member 60 is cut into a perfect circle shape. Thereby, the pre-processed member 60 is formed into a disk shape having flat upper and lower surfaces and a circular outer periphery.

In the core material processing step, a step 611 is formed by cutting out a portion of the outer periphery of the processed body 61, and simultaneously, a plurality of holes 61h serving as the base of the plurality of through holes 52 in the upper electrode 50 are formed. For example, the manufacturer uses a drill or the like (not shown) to drill the holes 61h each having an inner diameter larger than that of each of the through holes 52 at positions where the through holes 52 are to be formed.

In the next SiC layer forming step S3, the manufacturer uses a CVD device (film forming device) (not shown) to form a film of the SiC stacked portion 54p on the surface of the processed body 61 (upper surface, lower surface, outer periphery, and inner periphery of each hole 61h) as shown in FIG. 4C, thereby forming a film formed product 62. When the film is formed by the CVD device, the processed body 61 is heated to high temperature (e.g., 1500° C.) to grow a SiC film on the surface of the processed body 61. The graphite forming the processed body 61 has heat resistance, so that the SiC stacked portion 54p is stacked on the surface of the processed body while maintaining a good processed shape. In addition, each hole 61h of the processed body 61 is blocked by the SiC that fills in as the film is formed. As described above, the film formed product 62 has the SiC stacked portion 54p having a thickness slightly larger than the thickness of the SiC layer 54 in the final shape of the upper electrode 50.

Finally, in the final shape processing step S4, the manufacturer performs processing such as cutting, polishing, and drilling on the film formed product 62 to complete the electrode body 51 having the through hole 52, which is the final shape of the upper electrode 50, as shown in FIG. 4D. At this time, the manufacturer cuts the SiC stacked portion 54p on the upper and lower surfaces of the film formed product 62 into a flat shape to process it to the designed thickness of the upper electrode 50 (the thickness of the SiC layer 54). At this time, the amount of SiC to be cut is reduced due to the presence of the pre-processed body 61. For this reason, even if the SiC layer 54 has high hardness, it may be formed without taking much time.

In the final shape processing step, the through holes 52 are formed in the SiC layer 54 closing each hole 61h. Since the inner diameter of the through hole 52 is smaller than the inner diameter of each hole 61h, a thickness of the SiC layer 54 is left on the inner periphery of each of the formed through holes 52. This prevents the graphite from being exposed at each of the through holes 52 in the upper electrode 50, and prevents the plasma generated in the plasma processing space 10s from coming into contact with the graphite in each of the through holes 52.

As described above, in the manufacturing method according to this embodiment, the processed body 61 (core material 53) similar to the upper electrode 50 is first processed, the SiC layer 54 is formed on the processed body 61, and the resulting film formed product 62 is further processed into its final shape. This makes it possible to perform the SiC layer forming step, which requires time-consuming film formation, in a short time with high accuracy, thereby improving the manufacturing efficiency of the entire manufacturing method.

Here, as a reference example, a conventional method for manufacturing the upper electrode 100 will be described with reference to FIG. 5. As shown in FIG. 5A, in the member preparing step, a member 101 that is significantly thinner than the plate thickness of the upper electrode 100 in its final shape is prepared as the core material. For example, the member 101 has a thickness that is 20% or less of the plate thickness of the upper electrode 100.

As shown in FIG. 5B, in the manufacturing method according to the reference example, the core material processing step S2 is not performed, and the SiC layer forming step S3 is performed on the member 101 to form the film formed product 102. In this SiC layer forming step, the film is formed over a long period of time using the CVD device so that the SiC stacked portion 54p has a sufficient thickness relative to the thickness of the member 101. For example, in the SiC layer forming step, the SiC stacked portion 54p is grown to have a thickness about 10 times the thickness of the member 101. This leads to a long time for the SiC layer forming step, which reduces throughput. In addition, this increases the amount of processing gas used for film formation and leads to an increase in power required for heating, resulting in significant cost.

In the manufacturing method according to the reference example, in the final shape processing step S4 after the SiC layer forming step shown in FIG. 5C, the SiC stacked portion 54p formed in the film formed product 102 is processed to form the final shape of the upper electrode 50. Specifically, in the final shape processing step, the film formed product 102 is cut into a disk shape with the member 101 interposed therebetween, the member 101 is taken out, and the two SiC bodies 103 grown on both sides (upper and lower sides) of the member 101 are cut out. Then, in the final shape processing step, the two SiC bodies 103 are fixed to each other to form a SiC structure 104, and the outer periphery of one of the SiC bodies 103 is cut to form the step portion 511. Furthermore, in the final shape processing step, the plurality of through holes 52 are drilled in the SiC structure 104 to form the final shape of the upper electrode 100.

That is, in the final shape processing step S4 of the manufacturing method according to the reference example, the final shape of the upper electrode 50 made of SiC is entirely processed. As described above, SiC has high hardness and poor processability. For this reason, the final shape processing step also takes a long time. As a result, in the manufacturing method according to the reference example, the overall work efficiency and processing accuracy of each step are poor, and the productivity of the upper electrode 50 is deteriorated.

In contrast, in the manufacturing method according to this embodiment shown in FIGS. 3 and 4, a previously processed processed body 61 is used as the core material 53, and the SiC layer 54 is formed on the surface of the processed body 61. This makes it possible to significantly shorten time required for the SiC layer forming step of forming the SiC layer 54 and the final shape processing step of processing the SiC layer 54. In particular, since the core material made of graphite has high processability, the core material processing step allows the processed body 61 to be obtained with high accuracy without taking much time.

The manufacturing method of the present disclosure is not limited to the above-described embodiment and may take various modifications. For example, the planar shape of the upper electrode 50 may be appropriately formed depending on the shape of the plasma processing chamber 10, and may be an elliptical shape or a polygonal shape. Even in this case, by using the processed body 61 having a shape that is similar to the final shape but is smaller than the final shape as the core material 53 in the core material processing step, it is possible to form the SiC stacked portion 54p on its surface in a short period of time and also to smoothly process it to the final shape.

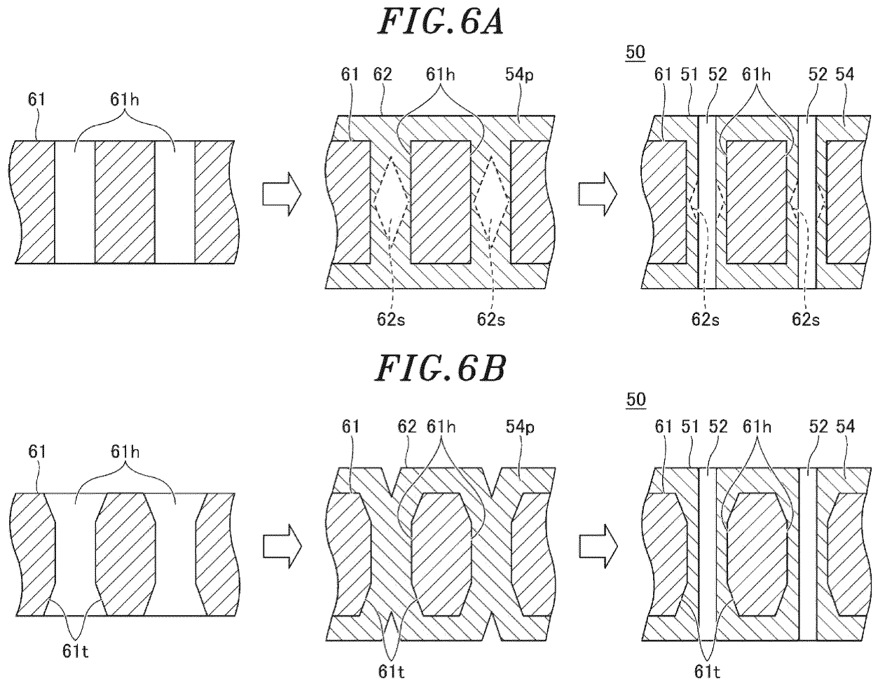

FIG. 6 is an explanatory diagram partially showing steps of a manufacturing method according to a modification. As shown in FIG. 6A, when the hole 61h having a constant inner diameter in the thickness direction is formed in the processed body 61 in the core material processing step (see the left diagram), SiC may not sufficiently penetrate into the hole 61h in the SiC layer forming step (see the middle diagram). In this case, the film formed product 62 has a cavity 62s. If the cavity 62s is large, a thin SiC layer 54 (or a portion without the SiC layer 54) may be generated in the cavity 62s (see the right diagram), when the through hole 52 is formed in the subsequent final shape processing step.

Therefore, in the manufacturing method according to a modification, as shown in FIG. 6B, in the core material processing step S2, tapered portions 61t may be formed on the upper and lower surfaces of the hole 61h of the processed body 61 so that the sidewall of the hole 61h widens toward each opening (see the left diagram). In FIG. 6B, the tapered portions 61t are formed on both the upper and lower surfaces of the hole 61h, but the tapered portion 61t may be formed on only one of the upper and lower surfaces of the hole 61h.

In this way, the tapered portion 61t formed in the core material processing step allows SiC to smoothly enter each hole 61h in the SiC layer forming step S3. This suppresses the generation of the cavity 62s in each hole 61h (see the middle diagram). Furthermore, the effect of the tapered portion 61t appears as a depression in the surface of the SiC layer 54, making it possible to guide a location where the through hole 52 is to be formed.

When each through hole 52 is drilled in the final shape processing step, the inner periphery of each through hole 52 is formed to have a substantially uniform thickness along the plate thickness direction (see the right diagram). That is, in the upper electrode 50, the inner periphery of each through hole 52 may be well covered with the SiC layer 54, and the influence of the plasma on the core material 53 may be suppressed.

### Second Embodiment

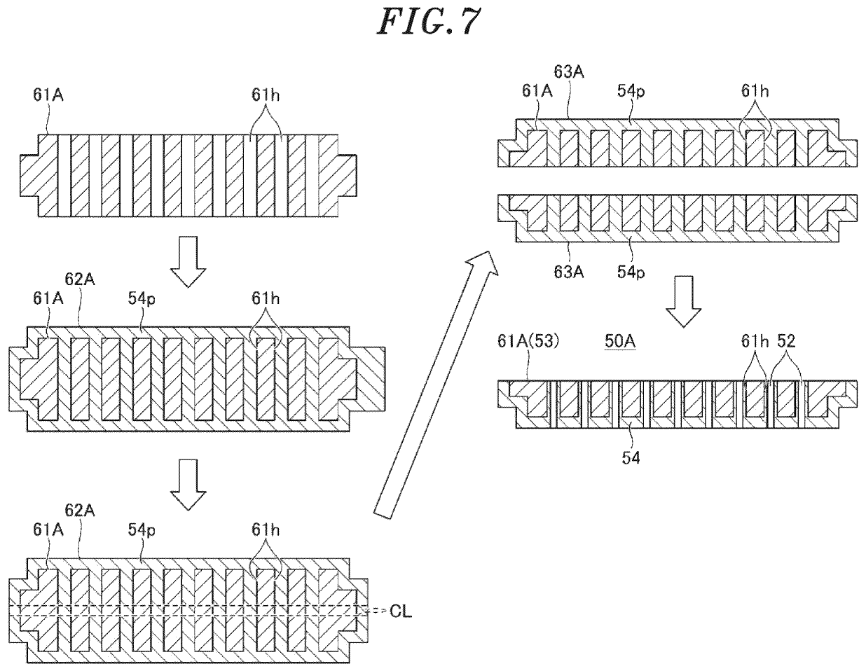

Next, a manufacturing method according to a second embodiment will be described with reference to FIG. 7. In the manufacturing method according to the second embodiment, in the core material processing step S2, as shown in the upper left diagram of FIG. 7, the pre-processed member 60 (see FIG. 4(a)) formed of graphite is processed to form a processed body 61A having a thickness at least twice that of the processed body 61 according to the first embodiment. The processed body 61A is formed to have a step on the outer periphery of each of the upper and lower surfaces. Similarly to the first embodiment, each hole 61h is formed to pass through the upper and lower surfaces of the processed body 61A.

Thereafter, as shown in the left middle diagram of FIG. 7, in the SiC layer forming step S3, the SiC stacked portion 54p is stacked on the entire surface of the processed body 61A by the CVD device to form the film formed product 62A. In the SiC layer forming step, SiC enters each hole 61h of the processed body 61A, so that the hole 61h is blocked by the SiC.

In the final shape processing step S4, a dividing step is performed to cut the intermediate portion of the film formed product 62A in the thickness direction. In the lower left diagram of FIG. 7, the film formed product is cut along two cutting lines CL (see dotted lines), but may be cut along a single cutting line CL depending on the thickness of the processed body 61A. The graphite processed body 61A is smoothly peeled off from each other in the cutting operation of the dividing step. By this dividing step, the film formed product 62A is divided into two divided molded products 63A having substantially the same shape, as shown in the upper right diagram of FIG. 7.

In the manufacturing method, after the two divided molded products 63A are formed, as shown in the right middle diagram of FIG. 7, a through hole forming step is performed to form each through hole 52, and a SiC processing step is performed to process the SiC layer 54 or the stepped portion 511 on the lower surface (the surface opposite to the divided surface) of the divided molded product 63A into the final shape. Thus, the manufacturing method according to the second embodiment can easily manufacture the upper electrode 50A having the SiC layer 54 on the lower surface facing (exposed to) the plasma processing space 10s. Further, the through hole forming step or the SiC processing step may be performed before the dividing step.

As described above, the manufacturing method according to the second embodiment divides the film formed product 62A, thereby enabling two upper electrodes 50A to be efficiently manufactured, and making it possible to reduce manufacturing cost. Furthermore, as long as the upper electrode 50A has the SiC layer 54 on the lower surface facing the plasma processing space 10s, the influence of the plasma may be sufficiently reduced even if the gas diffusion chamber 13b does not have the SiC layer 54 on the upper surface thereof.

### Third Embodiment

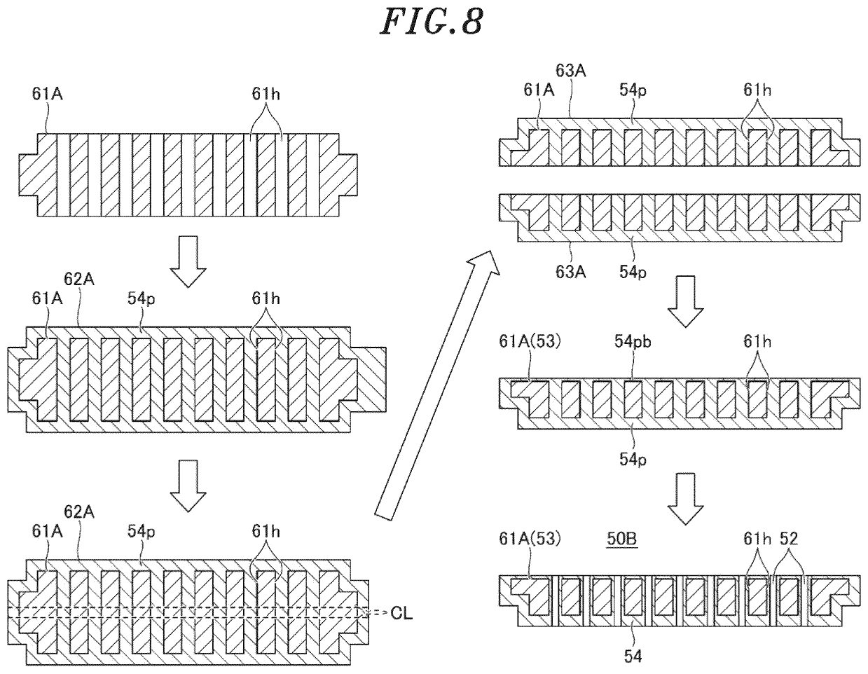

Next, a manufacturing method according to a third embodiment will be described with reference to FIG. 8. The electrode manufacturing method according to the third embodiment is different from the manufacturing method according to the second embodiment in that, after the dividing step in the second embodiment, a film forming step is performed to form a thin film 54pb of SiC on the surface (upper surface) on which the SiC stacked portion 54p is not formed. Since the other steps of the manufacturing method are the same as those in the second embodiment, a detailed description thereof will be omitted.

In the film forming step, the thin film 54pb is formed by the CVD device only on the upper surface of the divided molded product 63A. For example, the thickness of the thin film 54pb is set to 30% or less of the thickness of the SiC stacked portion 54p on the lower surface. Thereby, even when the film forming step is performed, the process may be completed in a short time. Furthermore, the upper electrode 50B formed through the through hole forming step or the SiC processing step has the SiC layer 54 on the upper surface thereof, so that it is possible to effectively avoid the influence of plasma in the gas diffusion chamber 13b.

### Fourth Embodiment

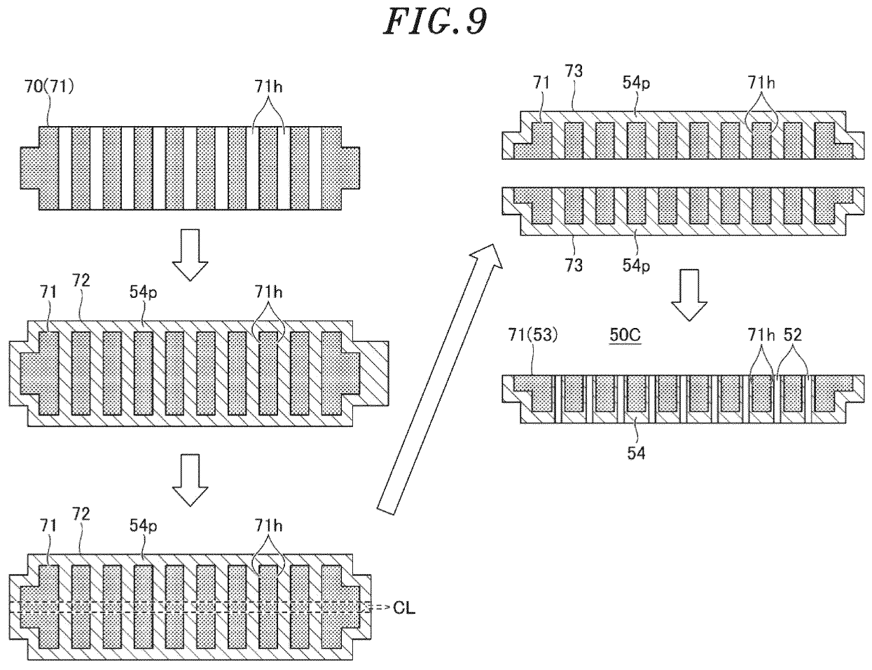

Next, a manufacturing method according to a fourth embodiment will be described with reference to FIG. 9. This manufacturing method is different from the electrode manufacturing methods according to the first to third embodiments in that a core material 70 made of a SiC sintered body is used. Like graphite, the SiC sintered body has the advantage of excellent heat resistance and low thermal expansion. Since the SiC sintered body is a porous body having fine pores, SiC is easily attached to the surface of the core material 70 when stacking the SiC film by the CVD method.

The pre-processed member (not shown) made of the SiC sintered body is formed by normal pressure or pressure sintering, hot pressing, or the like, and is processed in the core material processing step S2 to form a processed body 71. Even when the processed body 71 (SiC sintered body) is applied, the same manufacturing method as those described in the first to third embodiments may be employed.

FIG. 9 shows an example in which the processed body 71 (having the plurality of holes 71h and steps on both sides) having the same shape as in the second embodiment is formed, and the subsequent manufacturing methods are performed in the same manner. That is, in the manufacturing method, the SiC layer forming step S3 is performed on the processed body 71 formed in the core material processing step S2 to form a film formed product 72. Furthermore, in the final shape processing step S4, the film formed product 72 is divided into two divided molded products 73 by a dividing step, and a through hole forming step and a SiC processing step are further performed to form the final shape of the upper electrode 50C. In this manner, the electrode manufacturing method may easily form the upper electrode 50C having the core material 70 of the SiC sintered body. In addition, even when the SiC sintered body is applied, as in the third embodiment, the film forming step may be performed after forming the divided molded product 73, allowing the upper surface of the core material 70 of the SiC sintered body to be covered with the thin film 54pb of SiC.

### Fifth Embodiment

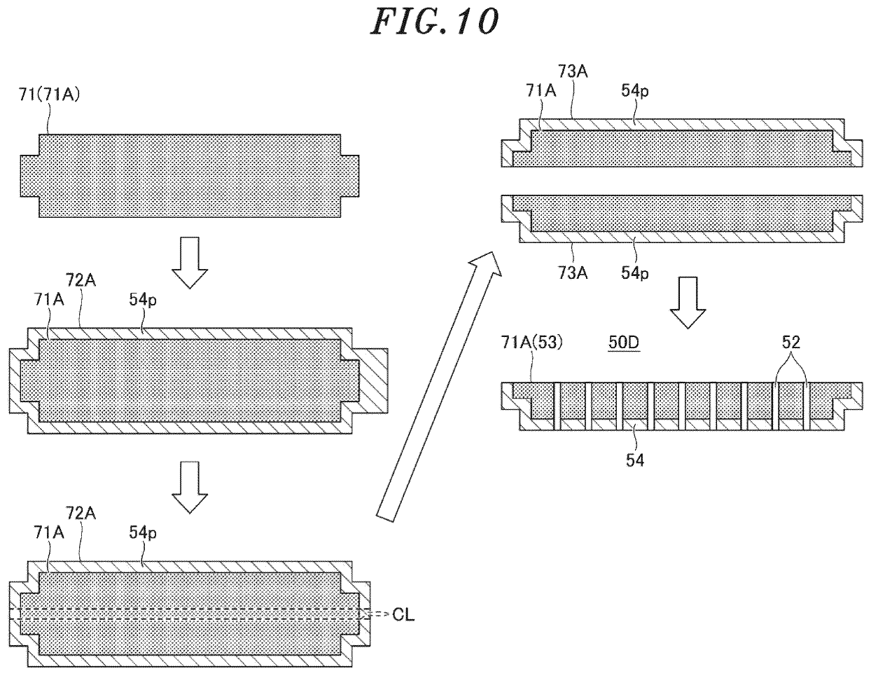

Next, an electrode manufacturing method according to a fifth embodiment will be described with reference to FIG. 10. In this manufacturing method, a core material 70 made of the SiC sintered body is used as in the fourth embodiment. However, in the core material processing step, the plurality of holes 71h are not formed in the processed body 71A.

In the manufacturing method, the SiC layer forming step S3 is performed on the processed body 71A, thereby forming a film formed product 72A that covers the processed body 71A with the SiC layer 54 (SiC stacked portion 54p). Furthermore, in the final shape processing step S4, two divided molded products 73A are formed by a dividing step, and then a through hole forming step and a SiC processing step are performed to manufacture the upper electrode 50D. In the through hole forming step, each through hole 52 is formed to pass through the core material 70 of the SiC sintered body and the SiC layer 54. Since the core material 70 of the SiC sintered body has a hardness that is approximately the same as, or lower than, the SiC layer 54, each through hole 52 may be formed smoothly.

Further, even in the manufacturing method in which the plurality of holes 71h are not formed in the core material processing step S2, the upper surface of the core material 70 of the SiC sintered body may be covered by performing the dividing step and then the film forming step. Subsequently, the through hole forming step or the SiC processing step may be performed. Alternatively, the manufacturing method may perform the through hole forming step and the SiC processing step before the dividing step.

The above-described embodiments include, for example, the following aspects.

### (Appendix 1)

A method for manufacturing a component for a plasma processing apparatus, the method comprising steps of:
(A) preparing a core material having a shape similar to but smaller than a final shape of the component;
(B) forming a SiC stacked portion on the core material by forming a SiC film; and
(C) removing at least a portion of the SiC stacked portion to form a SiC layer and process it into the final shape.

### (Appendix 2)

The method of Appendix 1, wherein
the component comprises a plurality of through holes, and
in the step (C), the plurality of through holes are formed simultaneously with formation of the SiC layer.

### (Appendix 3)

The method of Appendix 2, wherein, in step (A), the core material is prepared having a plurality of holes that penetrate in a thickness direction of the core material and are larger than the through holes.

### (Appendix 4)

The method of Appendix 3, wherein
in the step (A), the core material is prepared having the plurality of holes that are formed in a tapered shape with wall surfaces thereof widening toward an opening, and
in the step (B), the plurality of holes are closed by the SiC.

### (Appendix 5)

The method of Appendices 1 to 4, wherein a thickness of the core material prepared in the step (A) is 50% or more of a thickness of the final shape.

### (Appendix 6)

The method of Appendices 1 to 5, wherein the component is an upper electrode disposed to face a substrate support that supports a substrate, and in the step (C), a thickness of the SiC layer on a surface of the upper electrode facing the substrate support is thicker than a thickness of the SiC layer on other surfaces of the upper electrode.

### (Appendix 7)

The method of Appendices 1 to 6, wherein, in the step (C), a film formed product having the SiC stacked portion is cut in a direction perpendicular to the thickness direction of the film formed product.

### (Appendix 8)

The method of Appendices 1 to 7, wherein the core material comprises carbon.

### (Appendix 9)

The method of Appendix 8, wherein the core material is formed of graphite.

### (Appendix 10)

The method of Appendix 8, wherein the core material is formed of a SiC sintered body.

### (Appendix 11)

The method of Appendices 1 to 10, wherein, in the step (B), the SiC stacked portion is formed by chemical vapor deposition.

### (Appendix 12)

The method of Appendices 1 to 11, wherein the component is a showerhead that is disposed so that at least a portion thereof is exposed to a plasma processing space of the plasma processing apparatus, has a plurality of gas inlets, and is capable of introducing gas from the plurality of gas inlets into the plasma processing space.

### (Appendix 13)

A component for a plasma processing apparatus, the component comprising:
a component body,
wherein the component body comprises:
a core material having a shape similar to a final shape of the component but smaller than the final shape; and
a SiC layer stacked on a surface of the core material and covering the core material.

### (Appendix 14)

The component of Appendix 13, wherein the core material comprises carbon.

### (Appendix 15)

The component of Appendix 14, wherein the core material is formed of graphite.

### (Appendix 16)

The component of Appendix 14, wherein the core material is formed of a SiC sintered body.

### (Appendix 17)

The component of Appendices 13 to 16, wherein the component body has a through hole penetrating in a thickness direction of the component body.

### (Appendix 18)

The component of Appendix 17, wherein
the core material has a plurality of holes larger than the through hole, and wall surfaces forming the plurality of holes are tapered to widen toward an opening, and
the through hole is formed by covering the wall surface of each of the holes with the SiC layer.

### (Appendix 19)

The component of Appendices 13 to 18, wherein
the component is a showerhead that is disposed so that at least a portion thereof is exposed to a plasma processing space of the plasma processing apparatus, has a plurality of gas inlets, and is capable of introducing gas from the plurality of gas inlets into the plasma processing space.

The electrode manufacturing method and the electrode according to the above embodiment are one example of a method for manufacturing a component for a plasma processing apparatus and a component, and are not limited thereto. Other examples of the component for the plasma processing apparatus may include an exhaust net disposed in the gas discharge port 10e.

The manufacturing method and components according to the embodiments disclosed herein are to be considered in all respects as illustrative and not restrictive. The embodiments may be changed and modified in various ways without departing from the spirit and scope of the appended claims. The features described in the above embodiments may be adapted to other configurations as long as they are not contradictory, and may also be combined as long as they are not contradictory.

The electrode disclosed herein can be applied to any type of device, including Inductively Coupled Plasma (ICP), Radial Line Slot Antenna (RLSA), Electron Cyclotron Resonance Plasma (ECR), and Helicon Wave Plasma (HWP).

This application claims priority to Japanese Patent Application No. 2022-120798, filed with the Japan Patent Office on Jul. 28, 2022, the entire contents of which are incorporated herein by reference.

1. A method for manufacturing a component for a plasma processing apparatus, the method comprising steps of:
(A) preparing a core material having a shape similar to but smaller than a final shape of the component;
(B) forming a SiC stacked portion on the core material by forming a SiC film; and
(C) removing at least a portion of the SiC stacked portion to form a SiC layer and process it into the final shape.

2. The method of claim 1, wherein
the component comprises a plurality of through holes, and
in the step (C), the plurality of through holes are formed simultaneously with formation of the SiC layer.

3. The method of claim 2, wherein, in step (A), the core material is prepared having a plurality of holes that penetrate in a thickness direction of the core material and are larger than the through holes.

4. The method of claim 3, wherein
in the step (A), the core material is prepared having the plurality of holes that are formed in a tapered shape with wall surfaces thereof widening toward an opening, and
in the step (B), the plurality of holes are closed by the SiC.

5. The method of claim 1, wherein a thickness of the core material prepared in the step (A) is 50% or more of a thickness of the final shape.

6. The method of claim 1, wherein
the component is an upper electrode disposed to face a substrate support that supports a substrate, and
in the step (C), a thickness of the SiC layer on a surface of the upper electrode facing the substrate support is thicker than a thickness of the SiC layer on other surfaces of the upper electrode.

7. The method of claim 1, wherein, in the step (C), a film formed product having the SiC stacked portion is cut in a direction perpendicular to the thickness direction of the film formed product.

8. The method of claim 1, wherein the core material comprises carbon.

9. The method of claim 8, wherein the core material is formed of graphite.

10. The method of claim 8, wherein the core material is formed of a SiC sintered body.

11. The method of claim 1, wherein, in the step (B), the SiC stacked portion is formed by chemical vapor deposition.

12. The method of claim 1, wherein the component is a showerhead that is disposed so that at least a portion thereof is exposed to a plasma processing space of the plasma processing apparatus, has a plurality of gas inlets, and is capable of introducing gas from the plurality of gas inlets into the plasma processing space.

13. A component for a plasma processing apparatus, the component comprising:
a component body,
wherein the component body comprises:
a core material having a shape similar to a final shape of the component but smaller than the final shape; and
a SiC layer stacked on a surface of the core material and covering the core material.

14. The component of claim 13, wherein the core material comprises carbon.

15. The component of claim 14, wherein the core material is formed of graphite.

16. The component of claim 14, wherein the core material is formed of a SiC sintered body.

17. The component of claim 13, wherein the component body has a through hole penetrating in a thickness direction of the component body.

18. The component of claim 17, wherein
the core material has a plurality of holes larger than the through hole, and wall surfaces forming the plurality of holes are tapered to widen toward an opening, and
the through hole is formed by covering the wall surface of each of the holes with the SiC layer.

19. The component of claim 13, wherein
the component is a showerhead that is disposed so that at least a portion thereof is exposed to a plasma processing space of the plasma processing apparatus, has a plurality of gas inlets, and is capable of introducing gas from the plurality of gas inlets into the plasma processing space.
